(19) United States
(12) Patent Application Publication
(10) Pub. No.: US 2012/0012170 A1
(43) Pub. Date: Jan. 19, 2012

(54) PROCESSED SILICON WAFER, SILICON CHIP, AND METHOD AND APPARATUS FOR PRODUCTION THEREOF

(75) Inventors: Sean Erik FOSS, Skedsmokorset (NO); Krister MANGERSNES, Oslo (NO)

(73) Assignee: INSTITUTT FOR ENERGITEKNIKK, Kjeller (NO)

(21) Appl. No.: 12/838,695

(22) Filed: Jul. 19, 2010

(51) Int. Cl. H01L 31/0376

(52) U.S. Cl. 136/256

(57) ABSTRACT

A silicon crystal wafer or chip, and a method for processing a substantially pure or semiconductor level doped silicon crystal wafer or chip for adapting the wafer or chip for laser beam ablation of an electrically insulating surface layer carried on the wafer or chip. A layer of amorphous silicon of a thickness substantially larger than the thickness of the naturally obtained oxide layer, the amorphous silicon being a substantially pure or semiconductor level doped grade amorphous silicon, is produced on top of a substantially clean surface of the silicon crystal wafer or chip. A layer of the electrically insulating surface layer being substantially transparent to an optical wavelength of a laser beam that is extensively absorbed in the layer of amorphous silicon, is produced on the layer of amorphous silicon. The surface of the silicon crystal wafer or chip is irradiated by a pulsed laser beam of an optical energy fluence and a pulse duration adapted to melt and evaporize the layer of amorphous silicon in an area corresponding to a footprint of the laser beam, so as to ablate a corresponding area of the electrically insulating layer.

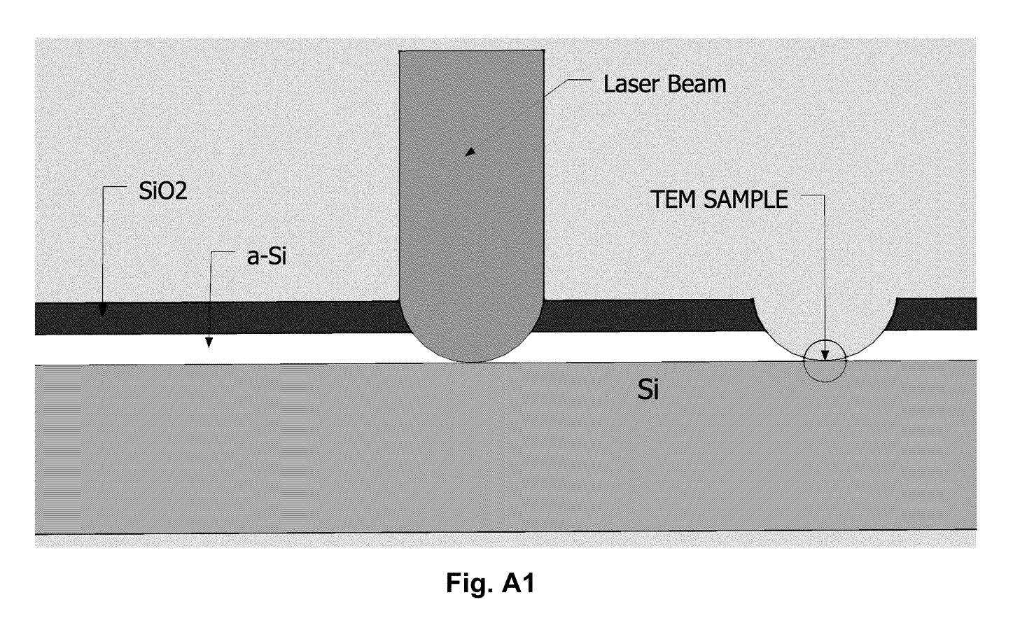

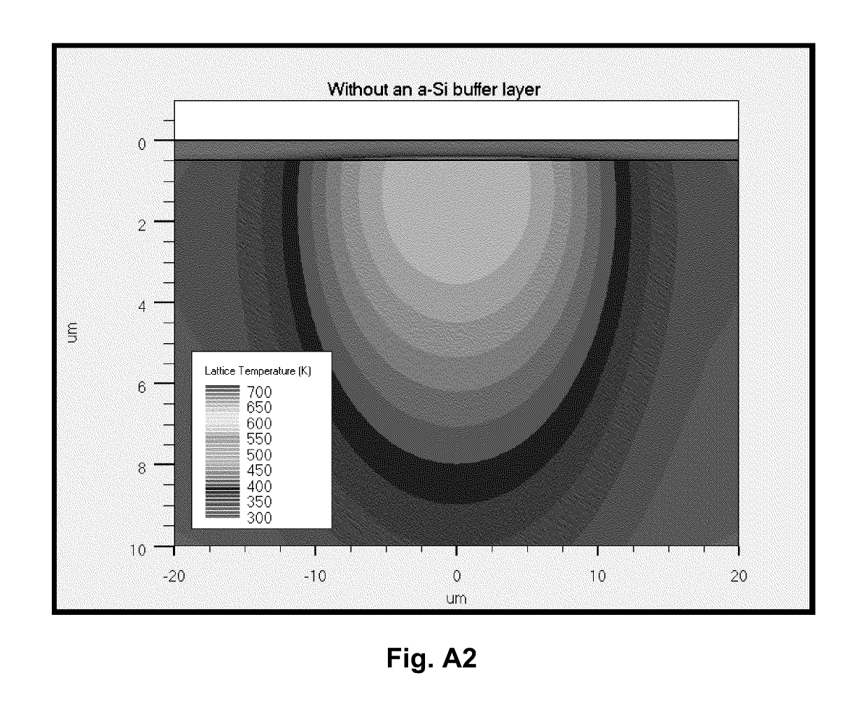

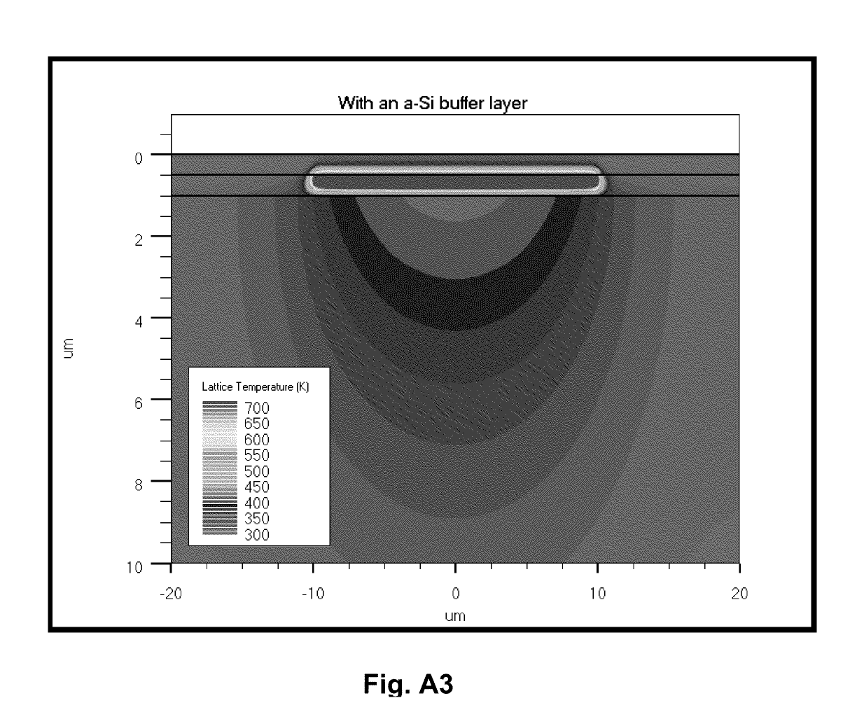

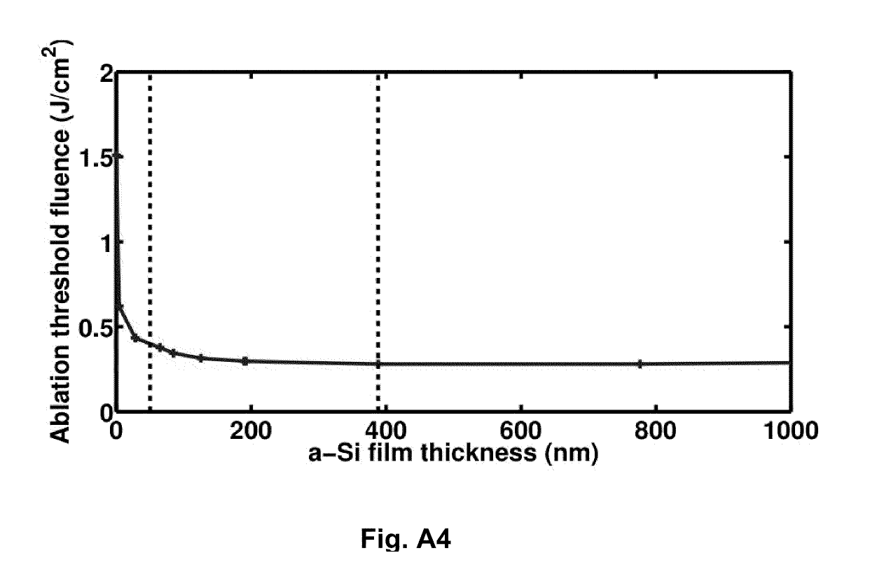

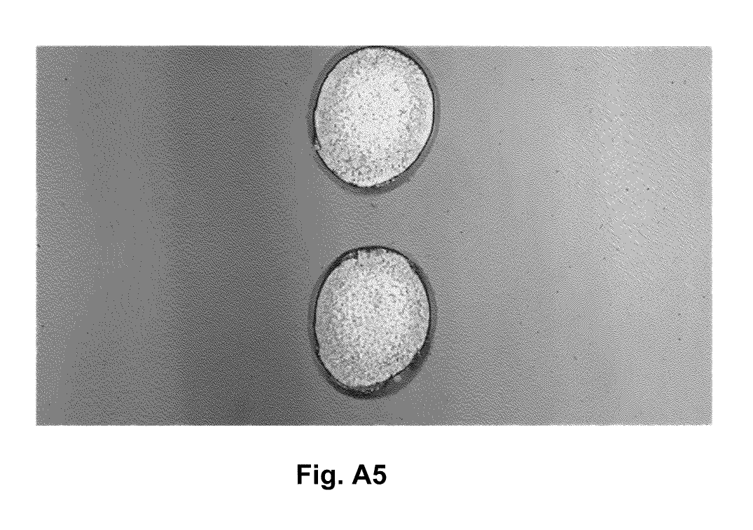

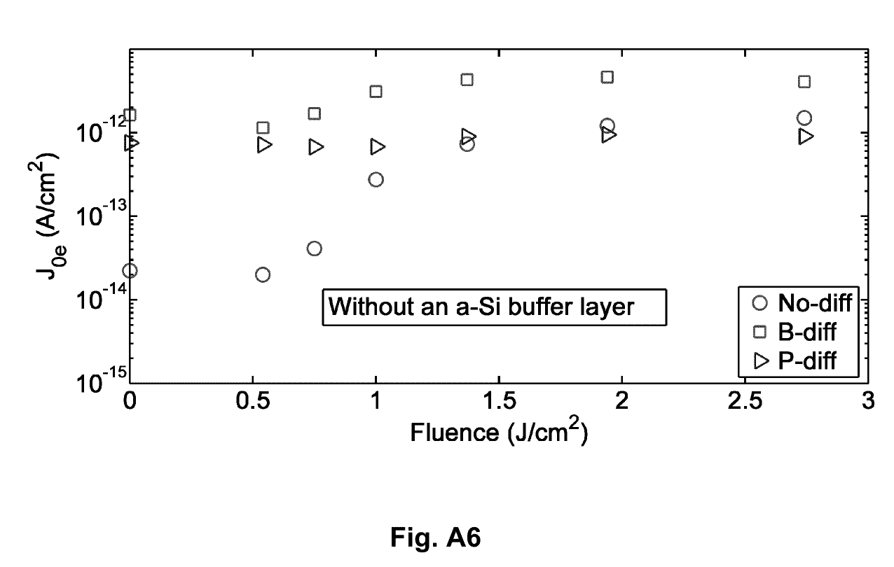

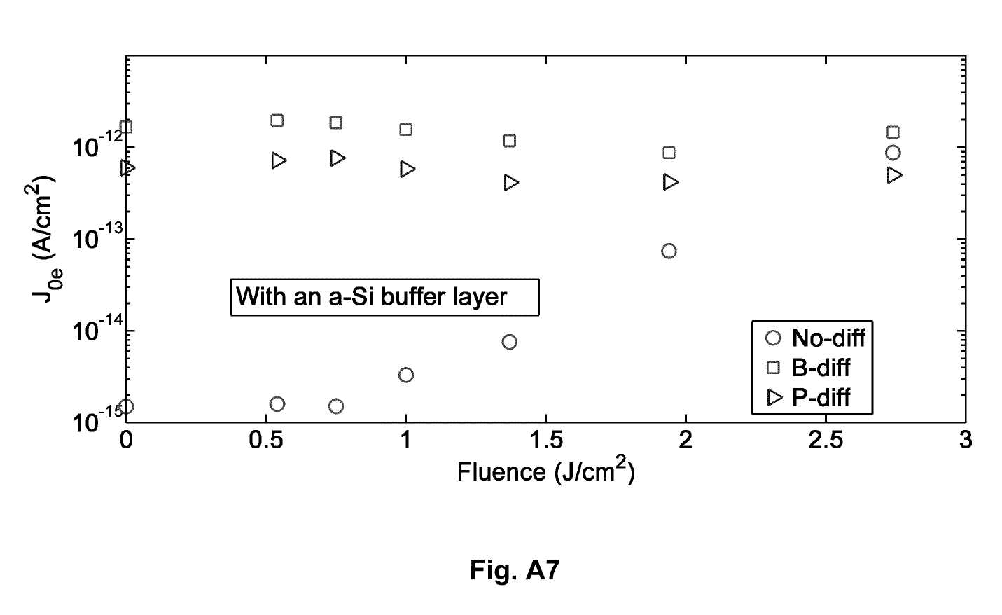

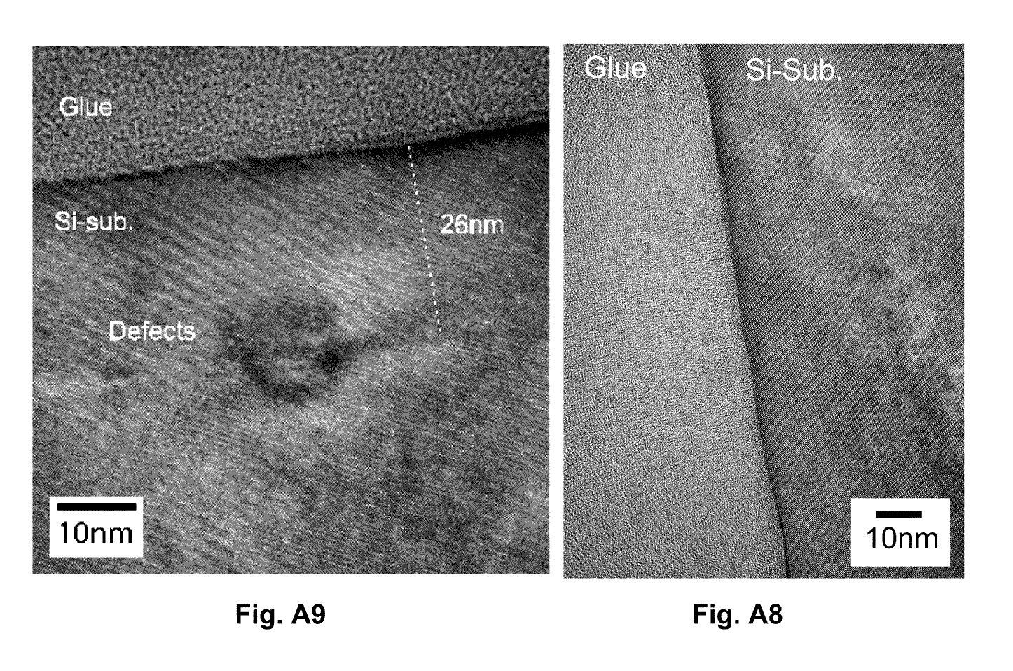

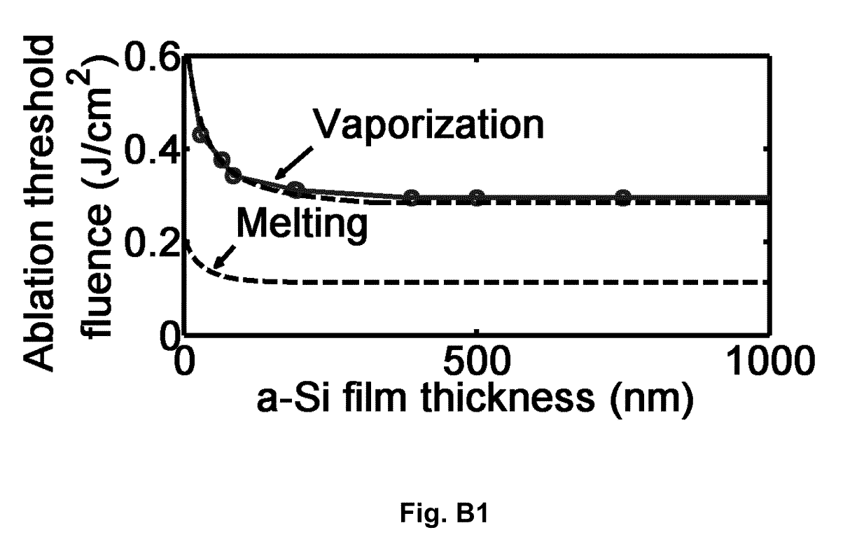

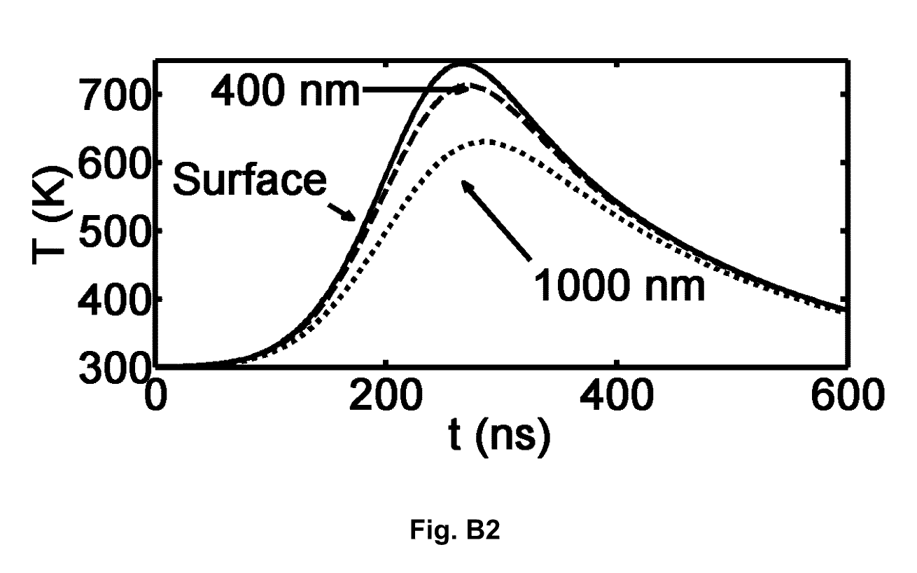

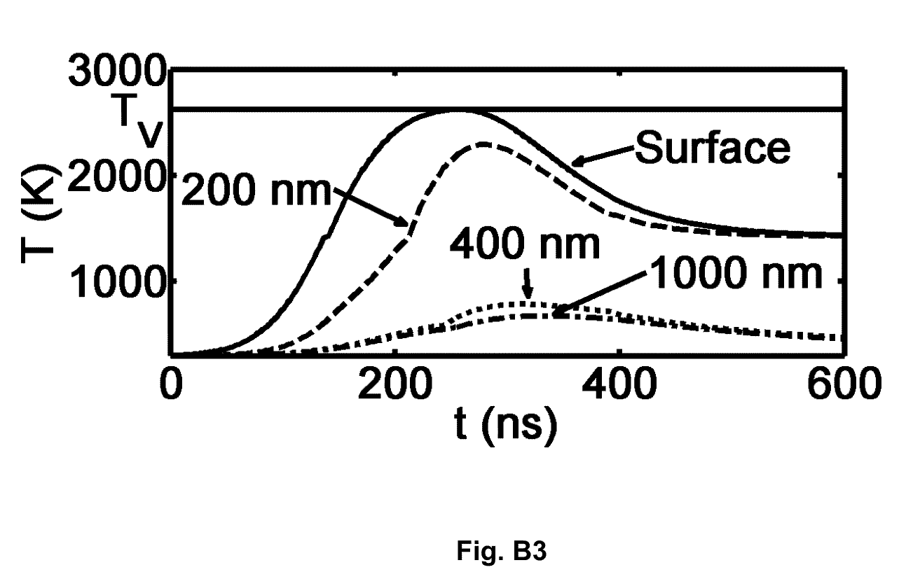

The file of this patent contains at least one drawing executed in color. Copies of this patent with color drawings will be provided by the Patent and Trademark Office upon request and payment of the necessary fee.

The present invention relates generally to the field of silicon material for electronics. More particularly, the invention relates to a processed silicon wafer for production of a silicon chip that is particularly well suited for production of efficient solar cell panels at a relatively low cost, and a method and an apparatus for production thereof.

In the following description, references made to other publications are indicated with numerals enclosed in square brackets, whereby relevant text of such mentioned references are included as part of this disclosure as they provide technical information that a skilled person in the art could find useful for understanding the background for particulars of this invention.

Lasers have in the recent years been shown to be a very promising tool for making local contacts on silicon solar cells through a dielectric layer[1-7]. Local ablation of material, typically at the surface of the material forming a photovoltaic cell, is done to produce an efficient solar cell that has reduced the total metal-semiconductor area of the solar cells, when compared to other solar cells, thus improving the efficiency of the solar cell device. Lasers in the nanosecond (ns) range are usually considered not particularly useful for such purpose, as they tend to induce significant thermal damage into the underlying silicon lattice. Solar cells that exhibit significant thermal damage in the underlying silicon lattice are not considered suitable for high efficiency solar cell concepts[4, 5, 8].

Back-contacted silicon solar cells have served as an alternative to conventional solar cells for more than 30 years.[1] Several different solar cell designs, such as metallization-wrap-through, emitter-wrap-through, and back-junction cells, have been developed. Back-junction solar cells have both the emitter and the complete metallization on the rear side. This eliminates the contact shading present in conventional solar cells. The sunward surface and back-side of the solar cell can therefore be independently optimized for optical and electrical performance, respectively. Moreover, having both contacts on the back-side may significantly simplify module assembly, and allow for an increased packing density of the cells.[2] Back-junction solar cells require high quality monocrystalline silicon wafers with long minority carrier lifetimes and excellent surface passivation. Low surface recombination losses in silicon solar cells can be obtained by passivating the surface by SiO2, SiNx, a-Si, Al2O3, and different stacks thereof, and by limiting the metal semiconductor contact area. Lasers have in the recent years been shown to be a very promising tool for making local contact openings to silicon through a dielectric layer. Cell concepts that earlier only have been possible to realize in low throughput, high-cost laboratory facilities are is expected to enter the commercial market in the coming years. Lasers with pulses within the nanosecond range are usually believed to be unsuitable for local contact opening through SiO2 and other dielectrics. This is because oxide is transparent to the most commonly used wavelengths, and the ablation takes place through an indirect process where the SiO2 is lifted off as a result of thermal expansion of molten or vaporized silicon. The relatively long laser pulses will affect the underlying silicon through heat dissipation. Laser energies above the ablation threshold have been shown to be detrimental to the minority carrier lifetime. The extent of the thermal diffusion can be approximated by the following expression:

I_{d}=\sqrt{2Dt}

where Id is the thermal penetration depth, D is the thermal diffusivity, and t is the pulse length of the laser. In silicon, the thermal penetration depth of a 100 ns long laser pulse will be around 3 μm at 1000 K. In this disclosure, it is shown that local contact can be made with a ns laser without damaging the crystalline silicon, c-Si, and thus maintain a high minority carrier lifetime, which is generally considered a necessity in high efficiency silicon solar cells. For simplicity, amorphous silicon is hereinafter referred to as a-Si. The solution proposed here is to add a buffer layer of plasma enhanced chemical vapour deposited (PECVD) hydrogenized amorphous silicon, a-Si:H, between the dielectric oxide layer and the crystalline silicon, and then take advantage of the thermal diffusivity of a-Si, which is two orders of magnitude lower than that of silicon, to sustantially avoid the laser damage of the crystalline silicon. The higher optical absorption coefficient of a-Si compared to crystalline silicon also contributes to the concentration of laser energy absorption within the a-Si buffer layer.

In the following, the invention will be elucidated by referring to experiments carried out, observations made during experiments, their results, and calculations made in respect of the experiments, and with reference to the accompanying illustrations provided in FIGS. A1 through A9, wherein:

FIG. A1 is a color schematic drawing illustration of the laser ablation sequence and the cross section area used for TEM analysis.

FIG. A2 is a color plot drawing showing the temperature distribution in a Si sample covered with 500 nm SiO2 after a 90 ns laser pulse. The wavelength and beam width was 532 nm and 20 μm, respectively, and the beam power was set to 1×10exp8 W/cm2. The axis units are in micrometers, μm.

FIG. A3 is a color plot drawing showing the temperature distribution in a Si sample covered with 500 nm a-Si and 500 nm SiO2 after a 90 ns laser pulse. The wavelength and beam width was 532 nm and 20 μm, respectively, and the beam power was set to 1×10exp8 W/cm2. The axis units are in micrometers, μm.

FIG. A4 is a color plot drawing showing the laser ablation fluence threshold vs the thickness of the a-Si layer. The data can be divided into three different regions, as indicated in the figure, an exponentially decreasing region, a linearly decreasing region, and a constant threshold fluence region.

FIG. A5 is an optical microscope picture of local contact openings of SiO2 ablated together with a buffer layer of amorphous silicon on a crystalline silicon sample. The laser fluence used to make the openings was about 0.3 J/cm2; five times lower than the laser fluence needed to ablate crystalline silicon. The diameter of the ablated spots is 20 μM.

FIG. A6 is a color plot drawing illustration of local emitter saturation current density and local saturation current density for the doped and undoped samples, respectively, as a function of laser fluence for samples without an a-Si buffer layer, shown for undiffused samples (circles), P-diffused samples (triangles), and B-diffused samples (squares). The reference values for the nonablated samples are shown at zero fluence.

FIG. A7 is a color plot drawing illustration of local emitter saturation current density and local saturation current density for the doped and undoped samples, respectively, as a function of laser fluence for samples with a 500 nm thick a-Si buffer layer, shown for undiffused samples (circles), P-diffused samples (triangles), and B-diffused samples (squares). The reference values for the nonablated samples are shown at zero fluence.

FIG. A8 is a high resolution transmission electron microscope (HRTEM) picture of a sample where the SiO2 and the buffer layer of a-si have been ablated with a single laser pulse without detectable damage to the silicon crystal structure. The fluence used 0.3 J/cm2.

FIG. A9 is a HRTEM picture of a sample where the SiO2 and the buffer layer of a-Si have been ablated with a single laser pulse. The fluence used was 0.8 J/cm2, and considerable damage induced to the silicon crystal structure is clearly detectable.

Silicon (Si) wafers of n-type, Cz 1-3Ω-cm, were used in all the experiments. Before processing, the wafers were cleaned in “piranha” (H2SO4: H202, 4:1) and HF (5%).

In the experiments, laser ablation energy threshold was studied. One set of wafers was prepared for laser fluence ablation threshold experiments. Laser fluence is the pulse energy density, and it is given in units of J/cm2. In the following, the laser fluence is referred to at the peak of the Gaussian beam profile. The laser used is a Q-switched Nd:YVO4, diode pumped 532 nm laser with nanosecond pulses, and a 1ê2 spot diameter of 40 μm. For these experiments, the wafers were cut into four parts. Thereafter, a PECVD layer of a-Si of varying thickness (0-1000 nm) was deposited on the different samples. The samples were then covered with 500 nm of PECVD SiO2. The thickness of the a-Si layer was measured by a variable angle spectroscopic ellipsometer. Each sample was exposed to the same matrix of single laser pulses with varying fluence in the range 0.1-2 J/cm2. In this energy range, the pulse duration decreases close to linearly with increasing fluence, from 150 ns at 0.1 J/cm2 to 80 ns at 2 J/cm2. The ablation threshold of the oxide was then determined by visual inspection in an optical microscope.

In the experiments, local emitter saturation current was studied. A set of four wafers was prepared for phosphorus doping. Each wafer was doped on both sides by spraying on a diluted phosphorus containing dopant source with a custom built spray-on system and subsequent drying and in-diffusion in a belt furnace. The phosphorus source was P509 from Filmtronics. Similarly, four wafers were boron-doped with boron-A from Filmtronics as a dopant source. A third set of four wafers was left undoped. The diffused phosphorus layers had a sheet resistivity of 50±5 Ω/s\tilde{q}(measured on a p-type wafer added for monitoring the sheet resistance), while the more shallow boron emitters had sheet resistivities of 150±20 Ω/sq, After the diffusion, the phosphorus and boron containing glass layers were removed in HF (5%), in oxidized in a belt furnace using a compressed dry air atmosphere. The required back side surface passivation for lifetime measurements was obtained by depositing a thin layer of a-Si on the back side of the samples by parallel plate PECVD in an Oxford Plasmalab 133 system. The amorphous layer was deposited at 230° C. with a flow of 25 SCCM (SCCM denotes standard cubic centimeter per minute at STP) of undiluted silane, SiH4. On two wafers of each set, non-diffused, phosphorus diffused, and boron-diffused, a thicker layer of a-Si was deposited on the front side. All the wafers were then covered with 500 nm of PECVD SiO2 and cut into four samples of equal size. The different samples were exposed to a matrix of single laser pulses, covering approximately 20% of the sample area. The laser fluence was varied from 0.2 to 1.4 J/cm2. After the laser ablation, the SiO2 was stripped off in HF (5%). Thereafter, a new thin layer of a-Si was deposited on the front of all samples, using the same method as before. Finally, all samples were annealed for 2 min at 450° C. in a belt furnace.

Use was made of quasi-steady-state photoconductance technique measurements under high injection conditions to extract the local emitter saturation current. The effective saturation current before and after laser ablation was used together with the fraction, a, of the laser ablated area to the total sample area to calculate the emitter saturation current in the laser ablated spots, J_{oe,eff}=a×Jₒₑ+(1−a)×J_{oe,pass} where J_{oe,eff} is the effective emitter saturation current, is the local emitter saturation current in the laser ablated spots, and Jₒₑ is the emitter saturation current of the passivated sample before laser ablation. This gives Jₒₑ=a⁻¹[J_{oe,eff}−(1−a)×J_{oe,pass}] for the local emitter saturation current in the laser radiated spots. A similar analysis was done by Engelhart et al. when comparing contact openings made by ns and picosecond lasers.

In the experiments, high resolution transmission electron microscopy HRTEM was used to analyze the defects induced in the crystal lattice from the laser ablation at different laser energies with and without an a-Si buffer layer of 500 nm. Use was made of a 200 keV JEOL 2010F microscope equipped with a Gatan imaging filter and detector. Cross sectional samples were prepared by gluing two sample substrates together, front-to-front, with epoxy glue. The cross sectional samples were thinned using ion-milling with a Gatan precision ion-polishing system operated at 5 kV gun voltage. FIG. A1 shows the laser ablation process sequence, and the cross section area used for TEM analysis.

By the experiments made in respect of the present invention, the inventors have shown that it is possible to locally ablate a dielectric layer on silicon in a damage free way with the use of a long pulsed laser by adding a buffer layer of a-Si between the dielectric and the silicon. The a-Si has a larger optical absorption coefficient, and the thermal diffusivity is more than two orders of magnitude lower than that of crystalline silicon. Therefore, the laser energy will be confined to a much smaller volume, and the ablation takes place at significantly lower fluences. The laser fluence needed to ablate an a-Si film decreases with increasing film thickness up to a thickness of 400 nm, corresponding to the estimated thermal penetration depth of a-Si, where the threshold energy reaches its minimum value of about 0.3 J/cm2. a-Si is also known to be an excellent surface passivation layer for both p- and n-type silicon solar cells. The general idea of introducing an absorbing and insulating a-Si buffer layer, should be relevant also for lasers with shorter pulse durations than what has been used in the experiments disclosed herein, since further advantages should be obtainable as the thickness of the a-Si layer, thereby also the deposition time, can be significantly reduced.

In the following, other aspects of the invention are disclosed, with reference to the drawings and illustrations of FIGS. B1, B2 and B3.

The inventors of the present invention have found that, in the case of a frequency doubled Nd:YVO4 green laser, a dielectric SiO2 layer is highly transparent to the laser light, and the studies have shown that ablation of a layer of SiO2 on Si takes place through an indirect process, wherein silicon oxide is lifted off due to expansion of molten or vaporized silicon immediately below the SiO2 layer on the surface of the Si wafer or chip.

A layer of SiO2 deposited on n-type Cz silicon using a plasma enhanced chemical vapour deposition (PECVD) process, with the aim of making local contact openings on back-junction silicon solar cells, was ablated using a Q-switched Nd:YVO4, diode pumped 532 nm laser with nanosecond pulses, and a spot diameter of 40 μm. Laser pulses within the ns range are usually believed to be incompatible with processing of high efficiency solar cells because such long pulses induce too much damage into the underlying silicon lattice. This is due to thermal dissipation. In this work, a PECVD layer of a-Si:H between the n-type silicon and the dielectric layer is shown to absorb much of the laser radiation and allows for ablation at laser fluences lower than the ablation threshold of crystalline silicon. In addition, the a-Si:H layer serves as an excellent surface passivation layer for the silicon substrate. It is demonstrated that it is possible to ablate PECVD SiO2 in a damage free way with fluences five times lower than those needed to ablate crystalline Si. The results are verified experimentally with high resolution transmission electron microscopy of the crystal structure in the laser irradiated areas, and quasi-steady-state photoconductance measurements of emitter saturation currents. In addition, the energy transfer from a ns 532 nm Gaussian shaped laser beam to a SiO2 covered Si lattice with and without the a-Si:H buffer layer, is simulated.

A model that coincides very well with the experiments, such as the experiment mentioned above, is disclosed herein.

According to the present invention, the addition of a buffer layer of hydrogenized amorphous silicon, a-Si:H (a-Si for simplicity), between the SiO2 top layer and the Si bulk material will absorb much of the laser irradiation[7]. The studies disclosed herein indicate that the combination of high optical absorption and low thermal conductivity of a-Si, when compared to crystalline Si, c-Si, confines the laser energy to a much smaller volume. This makes it possible to ablate small portions of SiO2 from a larger top layer area of SiO2 on a wafer or chip a without introducing significant damage to the c-Si material, with a laser fluence five times lower than that needed to ablate SiO2 on crystalline silicon. In addition, the residual a-Si serves as an excellent surface passivation layer for the Si substrate[9-11]. a-Si is not a very well defined material as most of the material parameters are very sensitive to the deposition technique and parameters. Especially the absorption coefficient and the thermal conductivity vary over a broad range according to different references[12-19]. Previous work on laser interaction with a-Si has mostly focused on melting and recrystallization of a-Si, both experimentally[15, 20-22] and numerically[21, 23-25]. It is an object to provide a thermodynamic model that predicts the laser fluence ablation threshold of SiO2 on a-Si layers of varying thickness, and that also describes the heat distribution in the SiO2-a-Si—Si stack after laser irradiation, useful as a tool in respect of the present invention, for purposes such as controlling laser ablation process parameters.

FIG. B1 is a plot drawing illustration of fluence threshold for laser ablation as a function of the thickness of the a-Si film. The experimental data obtained by the inventors from reference 7 (solid line with circles) is shown together with the modelled data for surface melting and vaporization.

FIG. B2 is a plot drawing illustration of heat distribution in Si as a function of time at different depths after single pulse laser irradiation with a fluence of 0.32 J/cm2 and a pulse duration of 142 ns. x=0 (surface) corresponds to the top of the Si substrate.

FIG. B3 is a plot drawing illustration of heat distribution as a function of time at different depths in a stack of 300 nm a-Si on Si after single pulse laser irradiation with a fluence of 0.32 J/cm2 and a pulse duration of 142 ns. x=0 (surface) corresponds to the top of the a-Si film.

In the following, some theoretical considerations related to the present invention are disclosed.

Herein is proposed a thermodynamic model that predicts the laser fluence ablation threshold of SiO2 on a-Si layers of varying thickness, and that also describes the heat distribution in the SiO2-a-Si—Si stack after laser irradiation. The model is contemplated as a basis for steps of optimisation of a method that embodies the present invention, or as a basis for an embodiment of the present invention in a method or a computer program on a carrier that is made executable in a programmable apparatus, for producing a processed Si wafer or chip prepared for providing efficient electrical connections to parts of material of a Si wafer or Si chip.

To find an expression for the laser fluence ablation threshold some simple assumptions are made. It is assumed that the onset of melting or vaporization is given by a critical energy density ET=FT/Lth,eff, where FT is the threshold fluence. Lth,eff is the effective thermal diffusion length defined by Lₜₕ=\sqrt{2D_{eff}τₚ}, where Deff is the effective thermal diffusivity and τp is the pulse duration of the laser at full width half maximum. Deff is the ratio between the effective thermal conductivity, keff, and the volumetric heat capacity. keff is weighted between the thermal conductivity of a-Si and Si, also including a thermal resistance at the interface between the two. A version of this model, not including interface resistance, was proposed by Matthias et al., when investigating laser ablation of metal films on quartz[26]. Herein one also need to account for an optically absorbing substrate under the thin film. Assuming a uniform temperature rise throughout the volume defined by Lth,eff, it can be shown that the threshold fluence for melting is given by

$${F}_{TM} = \frac{Δ {T}_{M}}{( 1 - R ) [ ( 1 - {e}^{- α d} ) + ( 1 - {e}^{- β {d}_{s}} ) {e}^{- α d} ]} {C}_{P , eff} {L}_{th , eff} \qquad ( 1 )$$

ΔTM is the needed temperature increment for melting, d and ds are the thicknesses of the a-Si layer and the Si substrate, respectively. It is assumed that the transparent SiO2 constitutes a thermal barrier and only influences the reflection, R, at the surface. α and β are the optical absorption coefficients of a-Si and Si, respectively. Cp,eff is the effective volumetric heat capacity; linearly weighted between a-Si and Si. The corresponding model for the onset of surface vaporization is the same as for melting but with ΔTM replaced by ΔTv+ΔHm/Cp.a-Si, where ΔTv is the needed temperature rise for vaporization, ΔHm is the latent heat of melting, and Cp.a-Si is the volumetric heat capacity of a-Si. The parameters used in the model are taken from Table I. The respective values at 1000 K for the temperature dependent parameters, and a pulse duration of 142 ns, were used. The experimental data from reference 7 is plotted together with the static thermodynamic models for surface melting and vaporization in FIG. B1. There is a good fit between the experimental data and the static model for surface evaporation even without temperature dependent parameters, and with the assumption of a uniform temperature rise. Still, this model only gives an indication of the onset of evaporation and does not include any information about the actual temperature distribution within the film and the substrate. It should be noted that it has not been taken into account that the pulse length of the laser used varies with fluence as given in Table I. A more dynamic description that also includes phase transitions will require a solution of the total enthalpy version of the heat equation. The diameter of the laser spot used is much wider than the thermal diffusion length of a-Si, and it is a good approximation to solve the one-dimensional version of the equation[27].

$$\frac{\partial Δ H ( x , t )}{\partial t} = \frac{\partial }{\partial x} κ ( T ) ( \frac{\partial }{\partial x} T ( x , t ) ) + S ( x , t ) \qquad ( 2 )$$

κ(T) is the temperature dependent thermal conductivity, x is the depth from the top of the a-Si layer, and S(x,t) is the laser source given by

$$S ( x , t ) = \sqrt{\frac{4 ln 2}{π}} \frac{( 1 - R ) F \cdot α}{{τ}_{p}} exp ( - α x - 4 ln 2 - \frac{{( t - {t}_{peak} )}^{2}}{{τ}_{p}^{2}} ) \qquad ( 3 )$$

F is the fluence at the peak of the Gaussian pulse, and tpeak is the time for the peak fluence. The total enthalpy, ΔH, is given by[27]

$$Δ H ( T ) \approx {\int }_{{T}_{0}}^{T} ρ ( {T}^{′} ) {c}_{p} ( {T}^{′} ) d {T}^{′} + η ( T - {T}_{M} ) Δ {H}_{M} + {η ( T - {T}_{V} )}^{25} Δ {H}_{V} \qquad ( 4 )$$

T0 is the ambient temperature, and TM and TV are the melting and vaporization temperatures, respectively. η is the Heaviside function (1 or 0 if the argument is positive or negative, respectively) and ΔHm and ΔHv are the latent heat of melting and vaporization, respectively.

To omit numerical instabilities it is assumed that the phase transitions occur over a temperature interval of ΔT=5 K. The SiO2 is assumed to be optically transparent and thermally insulating, and is only influencing the surface reflection. The structure is at ambient temperature before the laser heating starts. The following initial and boundary conditions are used:

$${{{T ( x , t ) = {T}_{0} \vert}_{t = 0} T ( x , t ) = {T}_{0} \vert}_{x \to ∞} \frac{\partial T ( x , t )}{\partial x} = 0 \vert}_{x = 0} \qquad ( 5 )$$

A finite difference scheme was used to solve the total enthalpy heat equation. The simulation parameters are listed in Table I. a, c, and 1 in the table refer to amorphous Si, crystalline Si, and liquid Si, respectively

In FIG. B2 is shown the temperature distribution in a SiO2 covered silicon wafer at different depths after laser irradiation with a single laser pulse with a fluence of 0.32 J/cm2. In FIG. B3 is shown the temperature distribution in a similar sample, but now with a 300 nm buffer layer of a-Si. Here, one should observe that the a-Si obtains a much higher surface temperature, and that 0.32 J/cm2 is enough to reach the onset of surface vaporization. This result, and also results for a-Si layers of different thicknesses (not shown) are in good agreement with the experimental data.

TABLE I

| Parameters | Value/Expression | Reference |
|---|---|---|
| Absorption | a: 1.9 × 10⁵ | 28 |
| coefficient | c: 5.02 × 10³e^{T/430} | 20 |
| (cm⁻¹) | 1: 1 × 10⁶ | 23 |
| Density | a: 2.20 | 23 |
| (g/cm³) | c: 2.32 | 27 |
| | 1: 2.52 | 27 |
| Thermal | a: 1.3 × 10⁻¹¹ × (T-900)³ + | 20 |
| Conductivity | 1.3 × 10⁻⁹ × (T-900)² + | |
| (W/cm K) | 1 × 10⁻⁶ × (T-900) + 1 × 10⁻² | |
| | c: 1521/T^{1.226} (T < 1200K) | 20 |
| | 8.96/T^{0.502} (1200K <= T < 1690K) | |
| | 1: 0.62 | 29 |
| Heat capacity | a: 2.2 × (0.952 + 0.171 × T/685) | 20 |
| (J/cm³ K) | c: 2.32 × (0.711 + | 30 |
| | 0.255 × (T^{1.85} − 1)/(T^{1.85} − 0.255/0.711) | |
| | 1: 1.0 | 29 |
| Melting temp | a: 1420 | 27 |
| (K) | c: 1690 | 27 |
| Vaporization | 1: 2680 | 27 |
| temp. (K) | | |
| Interface | 0.0054 | 16 |
| thermal | | |
| resistance | | |
| (cm² K/W) | | |
| Latent heat of | a: 1250 | 27 |
| melting (J/K) | c: 1780 | 27 |
| Latent heat of | 1: 15000 | 27 |
| Vaporization | | |
| (J/K) | | |
| Reflection | a: 0.18 | Measured |
| | c: 0.18 | Measured |
| | 1: 0.07 | Calculated |
| | | with data |
| | | from ref 31 |
| Pulse duration, | −37 × F + 154 | Measured. |
| full width | | F is the peak |
| at half | | fluence in |
| maximum (ns) | | the Gaussian |
| | | beam profile |
| | | (J/cm²) |
| Pulse peak (ns) | 200 | Set |

In the following, considerations regarding interface thermal resistance are disclosed.

Kuo et al. measured the thermal resistance of the interface between a-Si films and crystalline Si[16]. The value used in the simulations, 0.54 mm2 K/W, is the resistance they measured for a structure with a native oxide between the a-Si and the Si. This value was found to give the best fit between the modelling and these experiments. A clean surface, prepared by pre-sputtering in a vacuum chamber, showed an interface resistance of 0.15 mm2 K/W[16]. A lower interface resistance increases the laser fluence ablation threshold in the model according to the invention, as less heat is contained in the film. The increased thermal resistance at the interface between a-Si and the Si (presumably provided by an oxide) is therefore considered an important element of improvement of substantially the damage-free laser-ablation process according to the invention.

Advantages and Applications of the Invention.

Application of the static thermodynamic model that describes the fluence threshold for pulsed laser ablation of SiO2 on Si with a buffer layer of a-Si of varying thickness, allows production of c-Si material based electronic components that are highly efficient, since ablation is obtained with almost no significant damage to the c-Si. Having also solved the heat equation for the SiO2-a-Si—Si stack, the temperature distribution within the a-Si film and the Si substrate may be predicted and used for controlling important parameters related to performing the method of the invention, and to control properties of the c-Si wafer or chip product that was subjected to the ablation process. A material according to the invention having an interface thermal resistance between a-Si and Si is important by allowing a lower laser fluence ablation threshold, and by effecting a protection of the c-Si lattice that is located under the SiO2 layer in the area where the SiO2 is ablated by the energy of the laser beam pulse. The results obtained in the various embodiments of the invention are in good agreement with the experimental data provided by the present inventors, illustrating the advantage of including in the model the expected contribution from the native oxide layer to the thermal resistance of the interface.

### LIST OF REFERENCES

1. P. Engelhart, N. P. Harder, T. Horstmann, R. Grischke, R. Meyer and R. Brendel, Conference Record of the 2006 IEEE 4th World Conference on Photovoltaic Energy Conversion (IEEE Cat. No. 06CH37747), 4 pp. 1CD-ROM (2006).
2. A. Grohe, C. Harmel, A. Knorz, S. W. Glunz, R. Preu, G. P. Willeke, presented at the 4^{th} IEEE World Conference on Photovoltaic Energy Conversion, Vols 1 and 2, 2006.
3. P. Engelhart, N. P. Harder, R. Grischke, A. Merkle, R. Meyer and R. Brendel, Progress in Photovoltaics 15 (3), 237-243 (2007).
4. P. Engelhart, S. Hermann, T. Neubere, H. Plagwitz, R. Grischke, R. Meyd, U. Klug, A. Schoonderbeek, U. Stute and R. Brendel, Progress in Photovoltaics 15 (6), 521-527 (2007).
5. S. Hermann, T. Neubert, B. Wolpensinger, N.-P. Harder and R. Brendel, presented at the 23rd European Photovoltaic Solar Energy Conference, Valencia, Spain, 2008.
6. A. Knorz, M. Peters, A. Grohe, C. Harmel and R. Prett, Progress in Photovoltaics 17 (2), 127-136 (2009).
7. K. Mangersnes, S. E. Foss and A. Thøgersen, Journal of Applied Physics 107 (4) (2010).
8. K. Mangersnes and S. E. Foss, presented at the 24th European PVSEC, Hamburg, Germany, 2009.
9. A. G. Aberle, Progress in Photovoltaics 8 (5), 473-487 (2000).
10. A. Bentzen, A. Ulyashin, E. Sauar, D. Grambole, D. N. Wright, E. S. Marstein, B. G. Svensson and A. Holt, presented at the 15th international Photovoltaic Science and Engineering Conference, Shanghai, China, 2005.
11. M. Hofmann, C. Schmidt, N. Kohn, J. Rentsch, S. W. Glunz and R. Preu, Progress in Photovoltaics 16 (6), 509-518 (2008).
12. N. Attaf, M. S. Aida and L. Hadjeris, Solid State Communications 120 (12), 525-530 (2001).
13. D. G. Cahill, M. Katiyar and J. R. Abelson, Physical Review B 50 (9), 6077-6081 (1994).
14. R. K. Endo, Y. Fujihara and M. Susa, High Temperatures—High Pressures 35-36 (5), 505-511 (2003).
15. M. G. Grimaldi, P. Baeri, M. A. Malvezzi and C. Sirtori, International Journal of Thermophysics 13 (1), 141-151 (1992).
16. B. S. W. Kuo, J. C. M. Li and A. W. Schmid, Applied Physics a-Materials Science & Processing 55 (3), 289-296 (1992).
17. S. Moon, M. Hatano, M. H. Lee and C. P. Grigoropoulos, International Journal of Heat and Mass Transfer 45 (12), 2439-2447 (2002).
18. S. Volz, X. Feng, C. Fuentes, P. Guerin and M. Jaouen, International Journal of Thermophysics 23 (6), 1645-1657 (2002).
19. H. Wada and T. Kamijoh, Japanese Journal of Applied Physics Part 2-Letters 35 (5B), L648-L650 (1996).
20. C. K. Ong, H. S. Tan and E. H. Sin, Materials Science and Engineering 79 (1), 79-85 (1986).
21. Y. R. Chen, C. H. Chang and L. S. Chao, Journal of Crystal Growth 303 (1), 199-202 (2007).
22. L. Mariucci, A. Pecora, G. Fortunato, C. Spinella and C. Bongiorno, Thin Solid Films 427 (1-2), 91-95 (2003).
23. Z. Yuan, Q. Lou, J. Zhou, J. Dong, Y. Wei, Z. Wang, H. Zhao and G. Wu, Optics and Laser Technology 41 (4), 380-383 (2009).
24. S. Tosto, Applied Physics a-Materials Science & Processing 71 (3), 285-297 (2000).
25. C. H. Chang and L. S. Chao, International Communications in Heat and Mass Transfer 35 (5), 571-576 (2008).
26. E. Matthias, M. Reichling, J. Siegel, O. W. Kading, S. Petzoldt, H. Skurk, P. Bizenberger and E. Neske, Applied Physics a-Materials Science and Processing 58 (2), 129-136 (1994).
27. D. Bauerle, Laser Processing and Chemistry, 2 ed. (Springer, 1996).
28. E. D. Palik, Handbook of Optical Constants of Solids. (pp: 571-586), Elsevier.
29. H. Kobatake, H. Fukuyama, I. Minato, T. Tsukada and S. Awaji, Applied Physics Letters 90 (9) (2007).
30. V. Palankovski, R. Schultheis and S. Selberherr, IEEE Transactions on Electron Devices 48 (6), 1264-1269 (2001).
31. G. E. Jellison and D. H. Lowndes, Applied Physics Letters 51 (5), 352-354 (1987)

1. A method for processing a substantially pure or semiconductor level doped silicon crystal wafer or chip for adapting the wafer or chip for laser beam ablation of an electrically insulating surface layer carried on the wafer or chip, comprising
producing on top of a substantially clean surface of the silicon crystal wafer or chip, a layer of amorphous silicon, the amorphous silicon being a substantially pure or hydrogenized or semiconductor level doped grade amorphous silicon, and
producing on the layer of amorphous silicon, an electrically insulating surface layer being substantially transparent to an optical wavelength of a laser beam that is extensively absorbed in the layer of amorphous silicon.

2. The method of claim 1, wherein producing the layer of amorphous silicon includes processing the layer of amorphous silicon to exhibit a predetermined optical absorbance at said optical optical wavelength of said laser beam.

3. The method of claim 2, wherein processing the layer of amorphous silicon includes hydrogenizing the amorphous silicon to a hydrogen content in a range from 5% to 15% atomic.

4. The method of claim 2, wherein the predetermined optical absorbance exhibits at least one absorbance peak at an optical wavelength of about or close to 532 nanometers.

5. The method of claim 1, wherein the wavelength of the laser beam is about or close to 532 nanometers.

6. The method of claim 1, wherein the thickness of the layer of amorphous silicon is preferably in a range from about 5 nanometers to about 300 nanometers, more preferably in a range from about 50 nanometers to about 200 nanometeres, and still more preferably about 100 nanometers.

7. The method of claim 1, comprising
producing on top of the clean surface of the crystal wafer or chip, a narrow silicon oxide layer having a thickness corresponding substantially to an oxide layer thickness obtained naturally by exposing a clean surface of the substantially pure or semiconductor level doped silicon crystal wafer or chip to a normal atmosphere mixture of gases at a normal atmospheric pressure and a normal room temperature, such that narrow silicon oxide layer becomes located between the clean surface of the crystal wafer or chip and the amorphous silicon layer.

8. The method of claim 1, wherein the thickness of the narrow layer of silicon oxide is about 1 to 5 nanometers

9. A substantially pure or semiconductor level doped silicon crystal wafer or chip adapted for laser ablation of an electrically insulating surface layer carried on the wafer or chip, comprising
on top of a substantially clean surface of the silicon crystal wafer or chip, a layer of amorphous silicon, the amorphous silicon being a substantially pure or hydrogeniszed or semiconductor level doped grade amorphous silicon, and on the layer of amorphous silicon, a layer of the electrically insulating surface layer being substantially transparent to an optical wavelength of a laser beam that is extensively absorbed in the layer of amorphous silicon.

10. The silicon crystal wafer or chip of claim 9, wherein the layer of amorphous silicon includes processing the layer of amorphous silicon exhibits a predetermined optical absorbance.

11. The silicon crystal wafer or chip of claim 10, wherein the layer of amorphous silicon includes amorphous silicon hydrogenized to a hydrogen content in a range from 5% to 15% atomic.

12. The silicon crystal wafer or chip of claim 10, wherein the predetermined optical absorbance exhibits at least one absorbance peak at an optical wavelength of about or close to 532 nanometers.

13. The silicon crystal wafer or chip of claim 9, wherein the wavelength of the laser beam is about or close to 532 nanometers.

14. The silicon crystal wafer or chip of claim 9, wherein the thickness of the layer of amorphous silicon is preferably in a range from about 5 nanometers to about 300 nanometers, more preferably in a range from about 50 nanometers to about 200 nanometeres, and still more preferably about 100 nanometers.

15. The silicon crystal wafer or chip of claim 9, comprising
on top of the clean surface of the crystal wafer or chip, and located between the clean surface of the crystal wafer or chip and the amorphous silicon layer, a narrow silicon oxide layer having a thickness corresponding substantially to an oxide layer thickness obtained naturally by exposing a clean surface of the substantially pure or semiconductor level doped silicon crystal wafer or chip to a normal atmosphere mixture of gases at a normal atmospheric pressure and a normal room temperature.

16. The silicon crystal wafer or chip of claim 15, wherein the thickness of the narrow layer of silicon oxide is about 1 to 5 nanometers.

17. A method for ablating a part of an electrically insulating layer covering a surface of a silicon crystal wafer or chip, comprising
providing said silicon crystal wafer or chip comprising on top of a substantially clean surface of the silicon crystal wafer or chip, a layer of amorphous silicon, the amorphous silicon being a substantially pure or hydrogenized or semiconductor level doped grade amorphous silicon, and on the layer of amorphous silicon, a layer of the electrically insulating surface layer being substantially transparent to an optical wavelength of a laser beam that is extensively absorbed in the layer of amorphous silicon, and
irradiating the surface of the silicon crystal wafer or chip by a pulsed laser beam of an optical energy fluence and a pulse duration adapted to melt and evaporize the layer of amorphous silicon in an area corresponding to a footprint or a cross section of the laser beam, so as to ablate a corresponding area of the electrically insulating layer.

18. The method of claim 17, wherein the laser beam wavelength is about or close to 532 nanometers, the optical energy fluence is between 0.3 and 0.5 Joules per square centimeter, preferably about 0.32 Joules per square centimeter, and the pulse duration is about 142 nanoseconds.

19. The method of claim 17, wherein providing said silicon crystal wafer or chip comprises providing said silicon crystal wafer or chip having on top of the clean surface of the crystal wafer or chip, and located between the clean surface of the crystal wafer or chip and the amorphous silicon layer, a narrow silicon oxide layer having a thickness corresponding substantially to an oxide layer thickness obtained naturally by exposing a clean surface of the substantially pure or semiconductor level doped silicon crystal wafer or chip to a normal atmosphere mixture of gases at a normal atmospheric pressure and a normal room temperature.

20. A method for controlling an apparatus for method for ablating a part of an electrically insulating layer covering a surface of a silicon crystal wafer or chip comprising
on top of a substantially clean surface of the silicon crystal wafer or chip, a layer of amorphous silicon, the amorphous silicon being a substantially pure or hydrogenized semiconductor level doped grade amorphous silicon, and on the layer of amorphous silicon, a layer of the electrically insulating surface layer being substantially transparent to an optical wavelength of a laser beam that is extensively absorbed in the layer of amorphous silicon, the method comprising controlling a pulsed laser beam source of said apparatus using the thermodynamic model that predicts the laser fluence ablation threshold of SiO2 on a-Si layers of varying thickness, as disclosed in the description under the chapter heading “Theoretical considerations”.

21. A computer program on a carrier comprising computer instruction executable in a programmable apparatus to carry out the steps of the method of claim 1.

22. A photovoltaic cell, comprising the substantially pure or semiconductor level doped silicon crystal wafer or chip produced by the method of claim 1.

23. A photovoltaic cell, comprising the crystal wafer or chip according to claim 9.

24. A photovoltaic cell, comprising the crystal wafer or chip produced in a programmable apparatus operated by the computer program of claim 21.
